(19) United States
(12) Patent Application Publication
(10) Pub. No.: US 2014/0190549 A1
(43) Pub. Date: Jul. 10, 2014

(54) SOLAR CELL AND SOLAR MODULE

(71) Applicant: Sanyo Electric Co., Ltd., Moriguchi City (JP)

(72) Inventor: Takahiro Haga, Osaka (JP)

(73) Assignee: Sanyo Electric Co., Ltd., Moriguchi City (JP)

(21) Appl. No.: 14/210,504

(22) Filed: Mar. 14, 2014

Related U.S. Application Data
(63) Continuation of application No. PCT/JP2012/066112, filed on Jun. 25, 2012.

(30) Foreign Application Priority Data
Sep. 23, 2011 (JP) 2011-208252

(51) Int. Cl. H01L 31/05

(52) U.S. Cl. CPC H01L 31/0516
USPC 136/244

(57) ABSTRACT

A solar module with improved output characteristics is provided. A finger portion (21a) includes a finger portion main body (21a1), a wide portion (21a2) which is wider than the finger portion main body (21a1) and is connected electrically to a wiring member (30), and a narrow portion (21a3) which is narrower than the finger portion main body (21a1). A finger portion (22a) includes a finger portion main body (22a1), a wide portion (22a2) which is wider than the finger portion main body (22a1) and is connected electrically to a wiring member (30), and a narrow portion (22a3) which is narrower than the finger portion main body (22a1). Wide portion (21a2) is arranged next to narrow portion (22a3) in the y-direction, and wide portion (22a2) is arranged next to narrow portion (21a3) in the y-direction.

### CROSS-REFERENCE TO RELATED APPLICATIONS

This is a continuation of International Application PCT/JP2012/066112, with an international filing date of Jun. 25, 2012, filed by applicant, the disclosure of which is hereby incorporated by reference in its entirety.

The present invention relates to a solar cell and a solar module.

### BACKGROUND

Solar modules including back contact solar cells connected electrically via wiring members, such as the one described in Patent Document 1, are conventionally known. In a back contact solar cell, an electrode does not have to be provided on the light-receiving surface. As a result, improved output characteristics have been realized in solar modules using back contact solar cells.

### PRIOR ART DOCUMENTS

### Patent Documents

Patent Document 1: Laid-Open Patent Publication No. 2009-266848

### SUMMARY

### Problem Solved by the Invention

In recent years, there has been growing demand for solar modules with even better output characteristics.

A primary object of the present invention is to provide a solar module with improved output characteristics.

### Means of Solving the Problem

The solar module of the present invention includes a solar cell and a wiring member. The solar cell has a first electrode and a second electrode on the one main surface. A wiring member is connected electrically to the solar cell. The first electrode and the second electrode each have a finger portion extending in a first direction and arranged alternatingly in another direction orthogonal to the first direction. The finger portion of the first electrode includes a first finger portion main body, a first wide portion, and a first narrow portion. The first wide portion is wider than the first finger portion main body. The first wide portion is connected electrically to the wiring member. The first narrow portion is narrower than the first finger portion main body. The finger portion of the second electrode includes a second finger portion main body, a second wide portion, and a second narrow portion. The second wide portion is wider than the second finger portion main body. The second wide portion is connected electrically to the wiring member. The second narrow portion is narrower than the second finger portion main body. The first wide portion is arranged next to the second narrow portion in the other direction. The second wide portion is arranged next to the first narrow portion in the other direction.

The solar cell of the present invention has a first electrode and a second electrode on the one main surface. The first electrode and the second electrode each have a finger portion extending in a first direction and arranged alternatingly in another direction orthogonal to the first direction. The finger portion of the first electrode includes a first finger portion main body, a first wide portion, and a first narrow portion. The first wide portion is wider than the first finger portion main body. The first wide portion is connected electrically to a wiring member. The first narrow portion is narrower than the first finger portion main body. The finger portion of the second electrode includes a second finger portion main body, a second wide portion, and a second narrow portion. The second wide portion is wider than the second finger portion main body. The second wide portion is connected electrically to the wiring member. The second narrow portion is narrower than the second finger portion main body. The first wide portion is arranged next to the second narrow portion in the other direction. The second wide portion is arranged next to the first narrow portion in the other direction.

### Effect of the Invention

The present invention is able to provide a solar module with improved output characteristics.

### BRIEF DESCRIPTION OF THE DRAWINGS

FIG. 1 is a simplified cross-sectional view of the solar module in a first embodiment.

FIG. 2 is a simplified rear view of a solar cell in the first embodiment.

FIG. 3 is a simplified rear view of a solar cell string in the first embodiment.

FIG. 4 is a simplified rear view of a solar cell in a second embodiment.

FIG. 5 is a simplified rear view of a solar cell string in the second embodiment.

FIG. 6 is a simplified rear view of a solar cell in a third embodiment.

FIG. 7 is a simplified rear view of a solar cell string in the third embodiment.

FIG. 8 is a simplified rear view of a solar cell in the fourth embodiment.

FIG. 9 is a simplified rear view of a solar cell string in the fourth embodiment.

FIG. 10 is a simplified rear view of a solar cell in the fifth embodiment.

### DETAILED DESCRIPTION

The following is an explanation of examples of preferred embodiments of the present invention. The following embodiments are merely examples. The present invention is not limited by the following embodiments in any way.

Further, in each of the drawings referenced in the embodiments, members having substantially the same function are denoted by the same symbols. The drawings referenced in the embodiments are also depicted schematically. The dimensional ratios of the objects depicted in the drawings may differ from those of the actual objects. The dimensional ratios of objects may also vary between drawings. The specific dimensional ratios of the objects should be determined with reference to the following explanation.

### 1st Embodiment

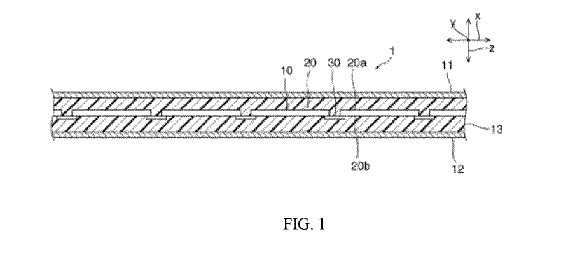

As shown in FIG. 1, the solar module 1 includes a solar cell string 10. The solar cell string 10 is arranged between a first protecting member 11 positioned on the light-receiving surface side, and a second protecting member 12 positioned on the back surface side. A bonding layer 13 is provided between the first protecting member 11 and the second protecting member 12. The solar cell string 10 is sealed by the bonding layer 13.

The first protecting member 11 can be composed of a translucent member such as a glass substrate or resin substrate. The second protecting member 12 can be composed of a glass substrate, or a resin substrate such as a resin sheet or a resin sheet containing interposed metal foil. The bonding layer 13 can be made of a resin such as an ethylene/vinyl acetate (EVA) copolymer, polyvinyl butyral (PVB), polyethylene (PE), or polyurethane (PU).

The solar cell string 10 includes a plurality of solar cells 20 arranged in the x-direction (the first direction). The solar cells 20 are connected electrically via a wiring member 30.

Each solar cell 20 has a first main surface 20a and a second main surface 20b. The solar cell 20 receives light primarily on the first main surface 20a. As a result, the first main surface 20a may be referred to as the light-receiving surface, and the second main surface 20b may be referred to as the back surface. The solar cell 20 may generate electricity only when light is received on the first main surface 20a constituting the light-receiving surface, or may be a bifacial solar cell which generates electricity when light is received on both the first main surface 20a and the second main surface 20b.

There are no particular restrictions on the type of solar cell 20 that is used. The solar cells 20 can be, for example, crystalline silicon solar cells using a crystalline silicon substrate.

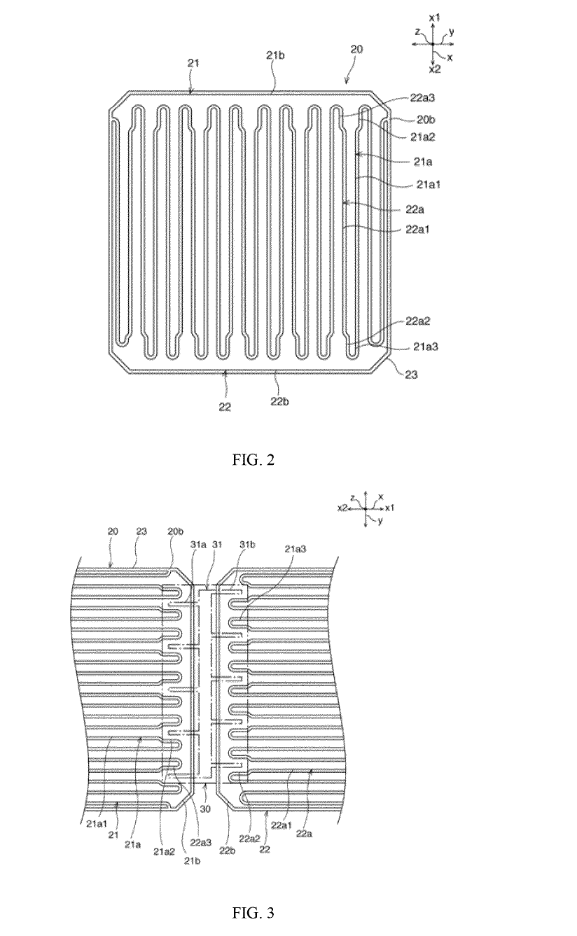

FIG. 2 is a simplified rear view of a solar cell 20. As shown in FIG. 2, the solar cell 20 has a first electrode 21 and a second electrode 22 on the second main surface 20b side. More specifically, the solar cell 20 has a photoelectric conversion unit 23, and a first electrode 21 and a second electrode 22 arranged on the main surface on the back surface side of the photoelectric conversion unit 23. One of the first electrode 21 or the second electrode 22 is the electrode used to collect electrons, and the other is the electrode used to collect holes.

Both the first electrode 21 and the second electrode 22 are comb-shaped. The first electrode 21 and the second electrode 22 are interdigitated. More specifically, the first electrode 21 and the second electrode 22 have a plurality of finger portions 21a, 22a, respectively. The finger portions 21a, 22a extend in first direction (the x-direction). The finger portions 21a, 22a are arranged alternatingly at given intervals in another direction (the y-direction which is orthogonal to the first direction (the x-direction).

The finger portions 21a are connected electrically to a busbar portion 21b. The busbar portion 21b is arranged on one side (the x1 side) of the finger portions 21a in the x-direction. The busbar portion 21b is provided on the x1 side of the solar cell 20 in the x-direction so as to extend from one end to the other in the y-direction.

Similarly, the finger portions 22a are connected electrically to a busbar portion 22b. The busbar portion 22b is arranged on the other side (the x2 side) of the finger portions 22a in the x-direction. The busbar portion 22b is provided on the x2 side of the solar cell 20 in the x-direction so as to extend from one end to the other in the y-direction.

As shown in FIG. 3, the first electrode 21 of one of two solar cells 20 adjacent to each other in the x-direction is connected electrically via a wiring member 30 to the second electrode 22 of the other solar cells 20. More particularly, the wiring member 30 has wiring 31. The wiring 31 has a first linear portion 31a which extends in the first direction (the x-direction), and a second linear portion 31b which also extends in the first direction (the x-direction) and is connected electrically to the first linear portion 31a. The first linear portion 31a is connected electrically to the finger portions 21a of the first electrode 21 of the solar cell 20 on the x2 side between the two solar cells 20 arranged adjacent to each other in the x-direction. The second linear portion 31b is connected electrically to the finger portions 22a of the second electrode 22 of the solar cell 20 on the x1 side between the two solar cells 20 arranged adjacent to each other in the x-direction.

The wiring member 30 and the solar cells 20 are bonded using an adhesive layer not shown in the drawing. The adhesive layer can be made of solder, a cured resin adhesive, or a cured resin adhesive containing a conductive material.

At least one of the finger portions 21a includes a finger portion main body 21a1, a wide portion 21a2 connected electrically to a first linear portion 31a of the wiring 31, and a narrow portion 21a3. The finger portions 21a may all include a finger portion main body 21a1, a wide portion 21a2 and a narrow portion 21a3, or there may be finger portions 21a which do not include at least one of a finger portion main body 21a1, a wide portion 21a2 and a narrow portion 21a3. For example, these finger portions 21a may be composed simply of a finger portion main body 21a1.

The width of the finger portion main body 21a1 in the y-direction is substantially constant. The width of the wide portion 21a2 in the y-direction is wider than the width of the finger portion main body 21a1 in the y-direction. The width of the wide portion 21a1 in the y-direction is preferably 1.2 to 1.8 times, and more preferably 1.5 to 1.75 times, the width of the finger portion main body 21a1 in the y-direction.

The width of the narrow portion 21a3 in the y-direction is narrower than the width of the finger portion main body 21a1 in the y-direction. The width of the narrow portion 21a3 in the y-direction is preferably 0.2 to 0.8 times, and more preferably 0.25 to 0.5 times, the width of the finger portion main body 21a1 in the y-direction.

Similarly, at least one of the finger portions 22a includes a finger portion main body 22a1, a wide portion 22a2 connected electrically to a second linear portion 31b of the wiring 31, and a narrow portion 22a3. The finger portions 22a may all include a finger portion main body 22a1, a wide portion 22a2 and a narrow portion 22a3, or there may be finger portions 22a which do not include at least one of a finger portion main body 22a1, a wide portion 22a2 and a narrow portion 22a3. For example, these finger portions 22a may be composed simply of a finger portion main body 22a1.

The width of the finger portion main body 22a1 in the y-direction is substantially constant. The width of the wide portion 22a2 in the y-direction is wider than the width of the finger portion main body 22a1 in the y-direction. The width of the wide portion 22a1 in the y-direction is preferably 1.2 to 1.8 times, and more preferably 1.5 to 1.75 times, the width of the finger portion main body 22a1 in the y-direction.

The width of the narrow portion 22a3 in the y-direction is narrower than the width of the finger portion main body 22a1 in the y-direction. The width of the narrow portion 22a3 in the y-direction is preferably 0.2 to 0.8 times, and more preferably 0.25 to 0.5 times, the width of the finger portion main body 22a1 in the y-direction.

Preferably, the sum of the width of the finger portion main bodies 21a1 in the y-direction and the width of the finger portion main body 21a1 in the y-direction, the sum of the width of the wide portions 21a2 in the y-direction and the width of the narrow portions 22a3 in the y-direction, and the sum of the width of the narrow portions 21a3 in the y-direction and the width of the wide portions 22a2 in the y-direction are substantially equal.

Each wide portion 21a2 and narrow portion 22a3 are arranged so as to overlap in the other direction (the y-direction). Also, each narrow portion 21a3 and wide portion 22a2 are arranged so as to overlap in the same direction (the y-direction). More specifically, the wide portion 21a2 is arranged at the tip of the finger portion 21a on the x1 side. In other words, the wide portion 21a2 is provided where the finger portion 21a connects to the busbar portion 21b. The narrow portion 22a3 is provided on the tip of the finger portion 22a on the x1 side. The wide portion 22a2 is provided on the tip of the finger portion 22a on the x2 side. In other words, the wide portion 22a2 is provided where the finger portion 22a connects to the busbar portion 22b. The narrow portion 21a3 is provided on the tip of the finger portion 21a on the x2 side.

However, in the solar module 1, carriers (holes and electrons) are generated in the photoelectric conversion unit 23 when the solar cells 20 are exposed to light. These carriers are collected by the first electrode 21 or the second electrode 22, and are extracted from the solar module 1 as electric power. Therefore, in order to improve the output characteristics of the solar module 1, the photoelectric conversion efficiency of the solar cells 20 has to be improved by suppressing loss due to the recombination of carriers.

In order to suppress the recombination of carriers, the distance traveled by the carriers generated by the photoelectric conversion unit 23 through the photoelectric conversion unit 23 to be collected by the first electrode 21 or the second electrode 22 has to be short. In other words, the finger portions 21a, 22a are preferably slender. However, when the finger portions are slender, it is difficult to connect wiring to the finger portions. For example, a short occurs when wiring makes contact with finger portions having another type of conductivity, and photoelectric conversion efficiency declines. Therefore, it is difficult from a practical standpoint to make the finger portions sufficiently slender.

By contrast, the finger portions 21a, 22a in the present solar module 1 include wide portions 21a2, 22a2 which are thicker than the finger portion main bodies 21a1, 22a1, and these wide portions 21a2, 22a2 are connected electrically to a wiring member 30. Thus, even when the finger portion main bodies 21a1, 22a1 are slender, an electrical connection can be established easily and reliably between the finger portions 21a, 22a and the wiring member 31. Narrow portions 21a3, 22a3 corresponding to the wide portions 21a2, 22a2 are also provided. In other words, the tips of the finger portions 21a, 22a, at which very few carriers are collected, are narrowed to form the narrow portions 21a3, 22a3. In this way, the number of finger portions 21a, 22a can be increased per unit area without increasing the interval between adjacent finger portion main bodies 21a1, 22a1. As a result, improved output characteristics can be realized.

From the standpoint of making the finger portion main bodies 21a1, 22a1 slender and making an electrical connection easier to establish between the finger portions 21a, 22a and the wiring 31, the width of the wide portions 21a2, 22a2 is preferably 1.2 times or more, and more preferably 1.5 times or more, the width of the finger portion main bodies 21a1, 22a1. However, when the width of the narrow portions 21a3, 22a3 is too small relative to the width of the finger portion main bodies 21a1, 22a1, the carriers sometimes cannot be collected sufficiently. Therefore, the width of the wide portions 21a2, 22a2 is preferably 1.8 times or less, and more preferably 1.75 times or less, the width of the finger portion main bodies 21a1, 22a1.

Also, in the solar module 1, the wide portions 21a2, 22a2 are provided where the finger portions 21a, 22a connect to the busbar portions 21b, 22b, which is where power tends to concentrate. Thus, collection loss of carriers due to the electrical resistance of the electrodes 21, 22 can be suppressed. As a result, even better output characteristics can be realized.

The following is an explanation of other examples of preferred embodiments of the present invention. In the following explanation, members having substantially the same functions as those in the first embodiment are denoted by the same reference numbers, and further explanation of these members has been omitted.

### 2nd and 3rd Embodiments

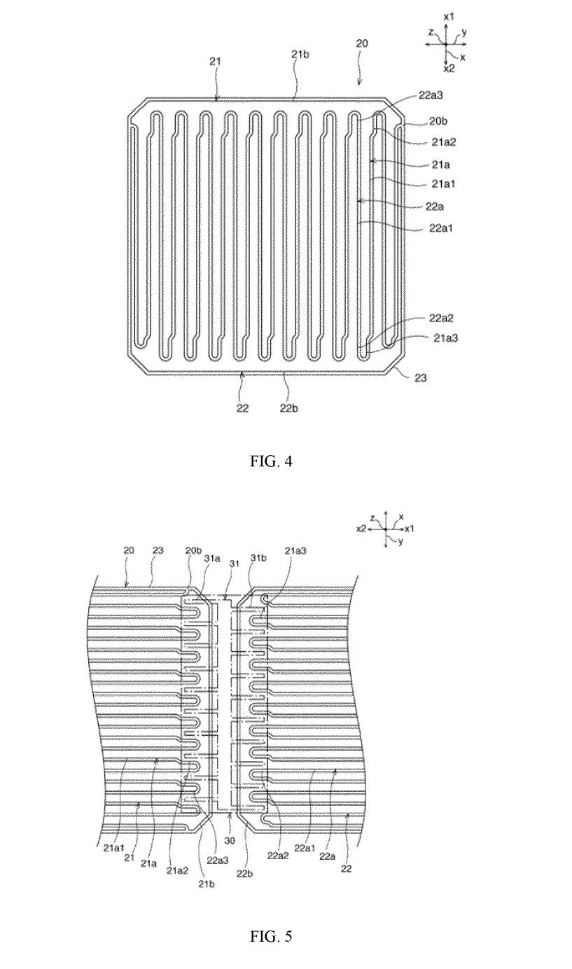

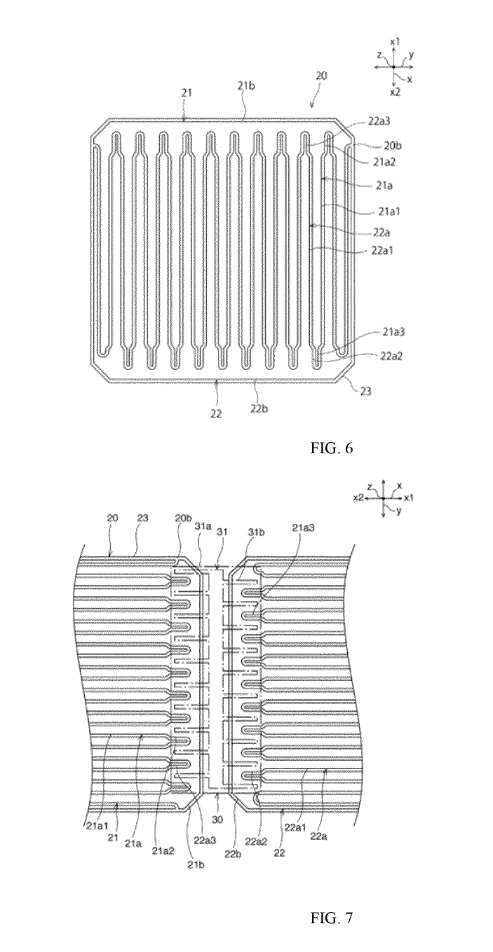

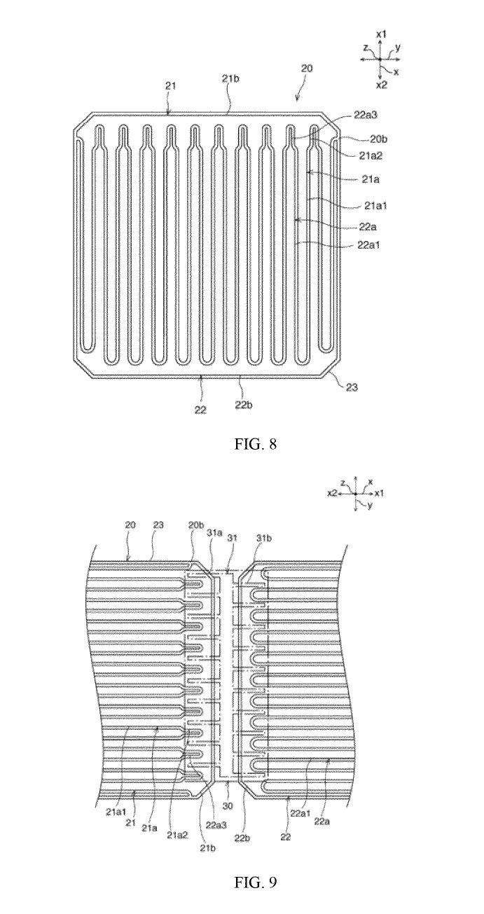

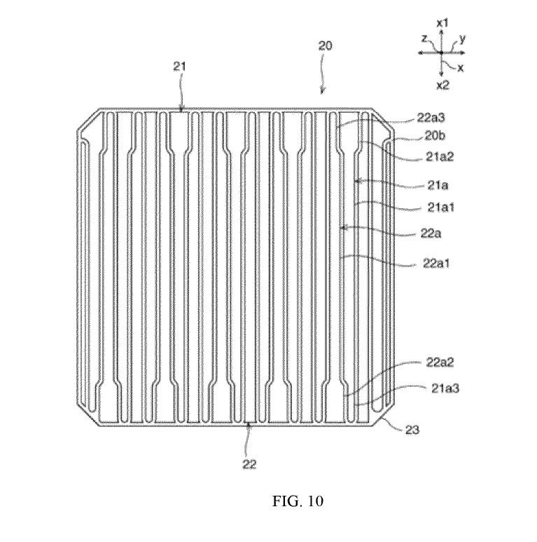

In the explanation of the example of the first embodiment, a wide portion 21a2, 22a2 was provided in one of the finger portions 21a, 22a in the y-direction. However, the present invention is not limited to this configuration. As shown in FIG. 4 through FIG. 7, a wide portion 21a2, 22a2 may be provided in all of the finger portions 21a, 22a. In this case, as shown in FIG. 4 and FIG. 5, the wide portions 21a2, 22a2 may have a shape which expands from only one side of the finger portion main bodies 21a1, 22a1 in the y-direction. Also, as shown in FIG. 6 and FIG. 7, the wide portions 21a2, 22a2 may have a shape which expands from both sides of the finger portion main bodies 21a1, 22a1 in the y-direction.

### 4th Embodiment

In the explanation of the example of the third embodiment, a wide portion 21a2, 22a2 and a narrow portion 21a3, 22a3 are provided in finger portions 21a and finger portions 22a. In the fourth example, by contrast, a wide portion 21a2 is provided only in finger portions 21a. A wide portion is not provided in finger portions 22a. Also, a narrow portion 22a3 is provided only in finger portions 22a, but a narrow portion is not provided in finger portions 21a. The first electrode 21, which includes finger portions 21a having a wide portion 21a2 but not a narrow portion, is the electrode used to collect the minority carrier. The second electrode 22, which includes finger portions 22a having a narrow portion 22a3 but not a wide portion, is the electrode used to collect the majority carrier. Loss due to the recombination of minority carriers can be suppressed by providing a wide portion 21a2 instead of a narrow portion in the first electrode 21 used to collect the minority carrier. As a result, improved photoelectric conversion efficiency can be realized.

### 5th Embodiment

In the explanation of the examples of the first through third embodiments, the first electrode 21 and the second electrode 22 each have busbar portion 21b, 22b. However, the present invention is not limited to this configuration. As shown in FIG. 10, the first electrode 21 and the second electrode 22 may each be composed only of finger portions 21a, 22a.

The present invention includes many embodiments not described herein. For example, each of the wide portions and narrow portions may be provided in the middle of the finger portions instead of at the tip or base.

The wiring member may be electrically connected directly to the busbar portion in addition to the wide portion.

The present invention includes many other embodiments not described herein. Therefore, the technical scope of the present invention is defined solely by the items of the invention specified in the claims pertinent to the above explanation.

### KEY TO THE DRAWINGS

1: Solar module
20: Solar cell
21: 1st electrode
22: 2nd electrode
21a, 22a: Finger portions
21a1, 22a1: Finger portion main body
21a2, 22a2: Wide portions
21a3, 22a3: Narrow portions
21b, 22b: Busbar portions
23: Photoelectric conversion unit
30: Wiring member

What is claimed is:

1. A solar module comprising:
a solar cell having a first electrode and a second electrode on a main surface, and
a wiring member electrically connected to the solar cell;
the first electrode and the second electrode each having:
a finger portion extending in the first direction and arranged alternatingly in another direction orthogonal to the first direction;
the finger portion of the first electrode including:
a first finger portion main body,
a first wide portion being wider than the first finger portion main body and connected electrically to the wiring member, and
a first narrow portion being narrower than the first finger portion main body;
the finger portion of the second electrode including:
a second finger portion main body,
a second wide portion being wider than the second finger portion main body and connected electrically to the wiring member, and
a second narrow portion being narrower than the second finger portion main body;
the first wide portion is arranged next to the second narrow portion in the other direction, and the second wide portion is arranged next to the first narrow portion in the other direction.

2. The solar module according to claim 1, wherein the wide portion is arranged on one side portion of the finger portion of the first electrode in the first direction, and the narrow portion is arranged on the other side portion.

3. The solar module according to claim 1, wherein the first electrode has a busbar portion arranged on one side of the finger portion in the first direction, and the second electrode has a busbar portion arranged on the other side of the finger portion in the first direction.

4. The solar module according to claim 1, wherein the first electrode and the second electrode each have a plurality of finger portions,
at least one of the plurality of finger portions of the first electrode having a first wide portion and a first narrow portion, and
at least one of the plurality of finger portions of the second electrode having a second wide portion and a second narrow portion.

5. A solar cell comprising:
a first electrode and a second electrode on a main surface;
the first electrode and the second electrode each having:
a finger portion extending in the first direction and arranged alternatingly in another direction orthogonal to the first direction;
the finger portion of the first electrode including:
a first finger portion main body,
a first wide portion being wider than the first finger portion main body and connected electrically to the wiring member, and
a first narrow portion being narrower than the first finger portion main body;
the finger portion of the second electrode including:
a second finger portion main body,
a second wide portion being wider than the second finger portion main body and connected electrically to the wiring member, and
a second narrow portion being narrower than the second finger portion main body;
the first wide portion is arranged next to the second narrow portion in the other direction, and the second wide portion is arranged next to the first narrow portion in the other direction.
